(19) United States
(12) Patent Application Publication
(10) Pub. No.: US 2017/0255228 A1
(43) Pub. Date: Sep. 7, 2017

(54) Wearable Electronic Device and Method of Manufacturing Thereof

(71) Applicants: Shanchun Yao, Chino Hills, CA (US); Wen Huang, CHINO HILLS, CA (US)

(72) Inventors: Shanchun Yao, Chino Hills, CA (US); Wen Huang, CHINO HILLS, CA (US)

(21) Appl. No.: 15/449,848

(22) Filed: Mar. 3, 2017

Related U.S. Application Data
(60) Provisional application No. 62/303,079, filed on Mar. 3, 2016.

(51) Int. Cl. G06F 1/16; H05K 1/18; G06F 1/32

(52) U.S. Cl. CPC G06F 1/163; G06F 1/1635; G06F 1/3234; H05K 1/189; G06F 1/3212

(57) ABSTRACT

A wearable electronic device and method of manufacture are disclosed. The electronic device includes at least a printed circuit board, a non-rechargeable battery, a processing system, and a package material. The printed circuit board, the non-rechargeable battery and the processing system are completely and hermetically sealed and surrounded by the package material, such as silicone resin. The package process may include at least a molding process wherein the battery, the PCB and the processing system are placed into a mold cavity and package material, such as liquid resin, is supplied into the cavity and cured. The wearable electronic device fully embedded in the package material and is affixed to an article of clothing or item worn by the user, such as wrist band, head band, sock, glove, and shoe.

### BACKGROUND

1. Field of the Invention

The invention relates generally to the field of consumer electronics. More particularly, the present invention relates in one embodiment to a wearable electronic device incorporated as part of an article of clothing for a user.

2. Description of Related Technology

Electronic devices perform an increasing number functions while continually being miniaturized, becoming highly portable, wearable and functional. Such electronic devices are generally carried in a pocket of a user, and may also be installed in a wearable device, attachable, for example, to a wrist, head or arm.

Wearable devices require portable power source such as batteries. Conventional wearable electronic devices utilize rechargeable batteries. Therefore, conventional wearable electronic devices require charging after the battery depletion. Furthermore, conventional wearable electronic devices are not waterproof and are easily damaged in tough environments while being worn by users. Thus there is a need to provide power source to wearable devices without recharging. Also, there is a need to provide durable and waterproof wearable electronic devices capable of enduring harsh and tough environments.

### SUMMARY OF THE INVENTION

See claims.

### BRIEF DESCRIPTION OF THE DRAWINGS

FIG. 1 illustrates exemplary functional units of a wearable electronic device in accordance with the present invention.

FIG. 2 illustrate a method of manufacturing a wearable electronic device in accordance with the present invention.

### DETAILED DESCRIPTION

Reference is now made to the drawings wherein like numerals refer to like parts throughout.

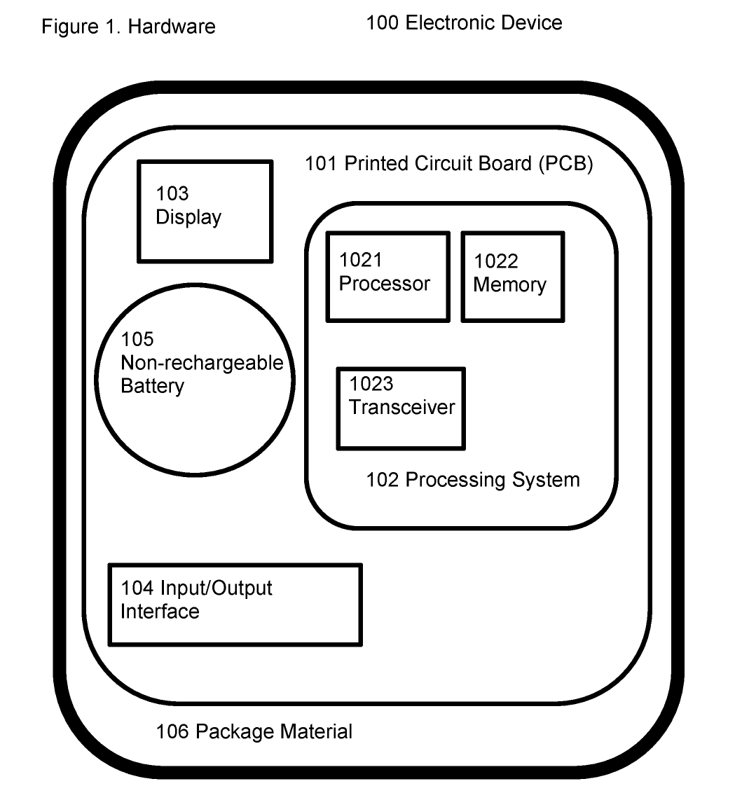

Referring to FIG. 1, an electronic device 100 may includes a printed circuit board (PCB) 101, a processing system 102, a display 103, an Input/Output interface 104, a non-rechargeable battery 105 and package material 106.

The PCB 101 may be rigid, flexible, or a combination of the two. The PCB 101 may including electrical connections and traces on one or more layers. The processing system 102, the display 103, the I/O interface 104 and the non-rechargeable battery 105 are assembled on the PCB 101, supported by the PCB 101, and coupled together by the connections and traces on the PCB 101.

In one embodiment, the processing system 102, the display 103, the I/O interface 104 and the non-rechargeable battery 105 are disposed, deposited, or mounted on a substrate of the PCB 101. The PCB 101, for example, may be manufactured from: polyacryclic (PA), polycarbonate, (PC) composite and arylonitrile-butadiene-styrene (ABS) substrates, blends or combinations thereof, or the like.

The processing system 102 may includes a processor 1021, memory 1022, and a transceiver 1023. The processing system 102 may be a single-chip system on a chip (SoC), or a number of chips. The processor 1021 may be an ARM 32-bit or 64-bit processor. The memory 1022 may store instructions necessary and executed by the processor 1021 in accordance with the present invention.

The transceiver 1023 may include a low power communication interface in accordance with low power communication protocol such as Bluetooth Low Energy (BLE), Bluetooth Smart, ANT, Zigbee, Wifi, NFC, and RFID. The transceiver 1023 may communicate with other wearable devices, mobile devices, servers and terminals.

The display 103 may include low power display such as an electronic paper (E-paper) display. The E-paper display relies on reflecting ambient light to be readable. The E-paper provides the advantage of consuming no energy when the display is static.

The I/O interface 104 may includes input devices and output devices. Input devices may include buttons, keypads, keyboard, and touch pads. Input devices may also include various sensors such as temperature, pressure, motion sensors. Input devices may further include various receivers such as location, data and information receivers. Output devices may include vibrators, speakers, LED's, and transmitter.

The non-rechargeable battery 105 may include Alkaline, Lithium, Li-ion and NiMH. The non-rechargeable battery may be coin cell type battery. The electronic device 100 is affixed to an article. The article may be worn by users. In order to operate the wearable electronic device for a period substantially the same as the period of use of the article. Thus, the battery life is substantially the same as a product life of the article.

In various embodiments, said article is: glove, headband, wristband, shoe, belt, pants, hat, head wear, shorts, shirts, button, mask, eye glasses, necklace, rings, wrist watch, arm band, shoulder pad ,chest band, underwear, socks, footwear, knee pad, knee brace.

For example, the product life of a pair of socks may be ten thousand hours of wearing. The product life of a golf glove may be twenty rounds of golfs or one thousand golf swings. Generally, the product life of the article is the time period from the first use of the article to the last use of the article. The product life of an article may be an expected product life or an actual product life.

To increase battery life, the powering of the processing system 102 may be activated based on an input or a sensor. The non-rechargeable battery 105 may also intermittently providing power to said system according to a duty cycle. The processing system 102 may include a power management unit which detects the remaining battery capacity. The power management unit may vary said duty cycle by increasing off (decrease on) interval based on a remaining battery capacity. For example, when the battery is low, the duty cycle may be adjusted such that the power-off interval becomes longer and power-on interval becomes shorter. Another example, the power management unit may adjust the duty cycle based on the remaining product life of the article. The remaining product life of a golf glove capable of enduring one thousand swings having one hundred swings is nine hundred swings. For example, the power manage unit may lengthen the power-off interval when the power management detects the remaining battery is low and the remaining product life is long. Furthermore, the power management unit may keep the same duty cycle when the remaining battery is low and the remaining product life is short.

The package material 106 may include silicone elastomer, thermoset plastic, thermoplastic resin, polymer, polycarbonate, elastomer, urethane, urethane elastomer, polyurethane, copolymers, thermoplastic vulcanizates, thermoplastic urethanes, olefinics, copolyamides, arylonitrile-butadiene-styrene (ABS), or blends thereof.

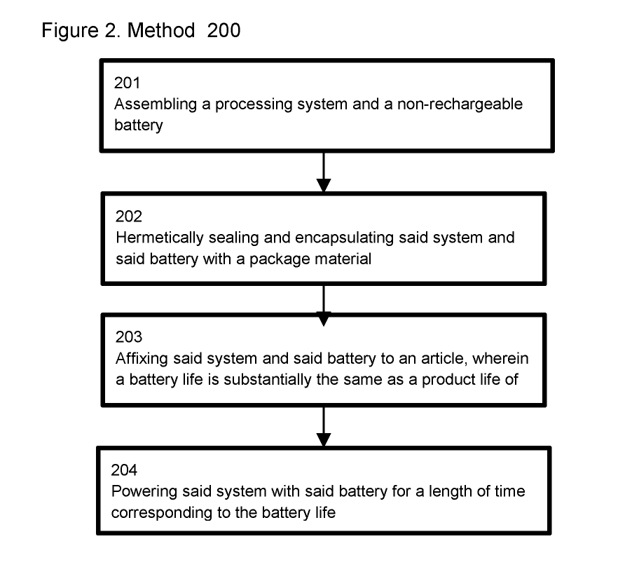

Referring to FIG. 2, the method of manufacturing the electronic device 100 starts with assembling the processing system 102 and the non-rechargeable battery 105 on the PCB 101 at step 201. The processing system 102, the display 103, the I/O interface 104 and the non-rechargeable battery 105 are disposed, deposited, or mounted on a substrate of the PCB 101.

At step 202, the package material 106 hermetically seals and encapsulates the assembled PCB 101, processing system 102 and non-rechargeable 105. The process of hermetically sealing and encapsulating may include providing a molding area (cavity) to inject the package material, supporting said system and said battery within said cavity, and injecting said package material to fill the area. The package material may be liquid silicone and be cured by curing agent or temperature.

At step 203, the electronic device 100 is affixed to an article. The processing of affixing may including stitching to fabric, glue, adhesive, and velcro. At step 204, the wearable device including the article and the electronic device 100 is activated and powered by the non-rechargeable battery for the length of time of the product life of the article.

1. A method for manufacturing an electronic device comprising:
assembling a processing system and a non-rechargeable battery;
hermetically sealing and encapsulating said system and said battery with a package material; and
powering said system with said battery for a length of time corresponding to a battery life.

2. The method of claim 1, further comprising:
affixing said system and said battery to an article, wherein said battery life is substantially the same as a product life of the article, wherein said product life of the article is the time period from the first use of the article to the last use of the article.

3. The method of claim 2, wherein the product life is an expected product life.

4. The method of claim 2, wherein the product life is an actual product life.

5. The method of claim 2, wherein said article including at least one of: glove, headband, wristband, shoe, belt, pants, hat, head wear, shorts, shirts, button, mask, eye glasses, necklace, rings, wrist watch, arm band, shoulder pad, chest band, underwear, socks, footwear, knee pad, and knee brace.

6. The method of claim 1, wherein:
powering comprising providing power to said system based on an input or a sensor.

7. The method of claim 1, wherein:
powering comprising intermittently providing power to said system according to a duty cycle.

8. The method of claim 7, further comprising
varying said duty cycle by increasing off (decrease on) interval based on a remaining battery capacity.

9. The method of claim 1, further comprising
displaying information received from said system using E-paper, low power display;
providing signal to said system from an input or sensor;
wherein said sensor including at least one of: button, pressure sensor, motion sensor, accelerometer, touch sensor;

10. The method of claim 1, further comprising
wirelessly receiving GPS signal.

11. The method of claim 1, further comprising
wirelessly communicating with short range/low power protocol, such as Bluetooth Low Energy (smart), ANT, NFC, Zigbee.

12. The method of claim 1. wherein said hermetically sealing and encapsulating comprising
providing a molding area (cavity) to inject package material;
supporting said system and said battery within said cavity;
injecting said package material to fill the area.

13. An electronic device comprising
a processing system;
a non-rechargeable battery configured to provide power for a length of time corresponding to a battery life;
a printed circuit board (PCB) configured to assemble said system and said battery; and
a package material configured to hermetically seal and encapsulate said PCB, said system and said battery.

14. The device of claim 13, wherein the PCB is flexible PCB.

15. The device of claim 14, wherein the processing system comprising memory, processor, data bus, and further comprising transceiver, display, input and output;
wherein the display is a low power display such as E-paper;
wherein the transceiver is a low power transceiver;
wherein the input includes at least one of: button, keypad, touch, temperature, pressure, motion sensor, location receiver;
wherein the output includes at least one of speaker, vibrator, LED.

16. A product comprising an article and the electronic device of claim 13, wherein said electronic device is affixed to said article, wherein said battery life is substantially the same as a product life of the article.

17. The product of claim 16, wherein said product life of the article is the time period from the first use of the article to the last use of the article.

18. The product of claim 17, wherein the product life is an expected product life.

19. The product of claim 17, wherein the product life is an actual product life.

20. The product of claim 16, wherein said article including at least one of : glove, headband, wristband, shoe, belt, pants, hat, head wear, shorts, shirts, button, mask, eye glasses, necklace, rings, wrist watch, arm band, shoulder pad, chest band, underwear, socks, footwear, knee pad, knee brace.

21. The electronic device of claim 13, wherein said battery configured to
provide power to said system based on an input or a sensor.

22. The electronic device of claim 13, wherein said battery configured to
intermittently provide power to said system according to a duty cycle.

23. The electronic device of claim 22, wherein said battery configured to
varying said duty cycle by increasing off (decrease on) interval based on a remaining battery capacity.

24. The electronic device of claim 13, wherein package material comprising silicon elastomer based, plastic composite.
